(19) United States
(12) Patent Application Publication
(10) Pub. No.: US 2026/0011594 A1
(43) Pub. Date: Jan. 8, 2026

(54) SHIPPING VEHICLE

(71) Applicant: GUDENG PRECISION INDUSTRIAL CO., LTD., New Taipei City (TW)

(72) Inventors: Ming-Chien Chiu, New Taipei City (TW); Chia-Ho Chuang, New Taipei City (TW); Kuo-Hua Lee, New Taipei City (TW); Jyun-Ming Lyu, New Taipei City (TW)

(73) Assignee: GUDENG PRECISION INDUSTRIAL CO., LTD., New Taipei City (TW)

(21) Appl. No.: 19/037,806

(22) Filed: Jan. 27, 2025

Related U.S. Application Data
(60) Provisional application No. 63/667,575, filed on Jul. 3, 2024.

(51) Int. Cl. H01L 21/677

(52) U.S. Cl. CPC H01L 21/67763

(57) ABSTRACT

A shipping vehicle includes a mobile transport device, an inflatable module, and a shipping box. The mobile transport device includes an inflatable receiving device and a gas connection port connected to the inflatable receiving device. The mobile transport device can be used for automated transportation or manual transportation, and can also be used as a transportation vehicle for transportation between factories or transportation to different areas outside the factories. The mobile transport device is used to carry the shipping box. The inflatable module continuously provides gas to the shipping box, which can effectively reduce the humidity inside the shipping box and greatly improve the problems of particles and VOC.

### CROSS-REFERENCE TO RELATED APPLICATION

This application claims priority to U.S. Provisional Application Ser. No. 63/667,575, filed Jul. 3, 2024, which is herein incorporated by reference.

### BACKGROUND

### Technical Field

The present disclosure relates to a shipping vehicle for shipping semiconductor containers.

### Description of Related Art

A wafer or a reticle must be protected by a wafer box or reticle box (hereinafter collectively referred to as the shipping box). The shipping boxes in a buffer area need to be placed on a trolley first, and then pushed to a side of a shipping vehicle. The shipping boxes on the trolley need to be placed in the shipping vehicle one by one. However, repeated handling will cause particle generation and personnel fatigue.

In general, a plastic bag will be put on the outside of the shipping box to prevent dust and external humidity from invading, and then the shipping box will be shipped to each factory through the shipping vehicle. However, a traditional shipping vehicle currently only has an air-conditioning function inside, but there is no design to maintain low humidity inside the shipping box. The defective rate of the shipping box will increase due to the distance, temperature, and storage method between factory A and factory B. In addition, the aforementioned plastic bag is made by using a machine to press the chuck of an Overhead Hoist Transfer (OHT) from top to bottom. However, this approach will cause the shipping box to deform, resulting in the generation of particles.

Furthermore, the traditional shipping vehicle generally has two layers, upper and lower, where shipping boxes can be placed. Although the traditional shipping vehicle has the air-conditioning function, the upper layer is close to the outside of the upper vehicle housing and the temperature will be higher due to sunlight. Even if there is air conditioning to maintain the internal temperature, the upper shipping box is still more susceptible to heat, causing an increase in volatile organic compounds (VOC).

Accordingly, how to provide a shipping vehicle to solve the foregoing problem becomes an important issue to be solved by those in the industry.

### SUMMARY

An aspect of the disclosure is to provide a shipping vehicle to solve the foregoing problem.

According to an embodiment of the disclosure, a shipping vehicle is suitable for shipping a semiconductor container. The shipping vehicle includes a mobile transport device, an inflatable module, and a shipping box. The mobile transport device includes an inflatable receiving device and a gas connection port connected to the inflatable receiving device. The inflatable module is configured on the mobile transport device. The inflatable module is configured to dock with the inflatable receiving device and provide a gas to be transmitted to the gas connection port. The shipping box is carried on the mobile transport device. The shipping box has a gas valve port. A position of the gas valve port corresponds to a position of the gas connection port. The gas valve port receives the gas and transmits the gas to the shipping box.

In one or more embodiments of the present disclosure, the inflatable module is a gas storage bottle.

In one or more embodiments of the present disclosure, the shipping box is configured to accommodate the semiconductor container. The semiconductor container has a gas receiving portion matching the gas connection port and the gas valve port. The gas receiving portion is configured to receive the gas and transfer the gas to the semiconductor container through the shipping box.

In one or more embodiments of the present disclosure, the mobile transport device further includes a transport rack and a plurality of wheels. The inflatable receiving device is configured on the transport rack. The transport rack is configured to carry the shipping box. The wheels are disposed on the transport rack and configured to move the transport rack.

In one or more embodiments of the present disclosure, the mobile transport device further includes a telescopic frame. The telescopic frame is disposed on the transport rack. The telescopic frame is configured to surround and fix the shipping box on the transport rack.

In one or more embodiments of the present disclosure, the telescopic frame includes a first rod body, a second rod body, and a pressing plat. The first rod body is connected to the transport rack and configured to abut against a side wall of the shipping box. The second rod body is sleeved with the first rod body and configured to linearly slide relative to the first rod body. The pressing plate is connected to one end of the second rod body and away from the first rod body. The pressing plate is configured to abut against and fix the shipping box.

In one or more embodiments of the present disclosure, the shipping vehicle further includes a rotating shaft member disposed between the first rod body and the transport rack. The first rod body is configured to rotate outwardly relative to the transport rack by the rotating shaft member to expand parallelly or rotate vertically to stand on the transport rack.

In one or more embodiments of the present disclosure, the shipping vehicle further includes a shock-absorbing module disposed between the transport rack and the wheels. The transport rack includes a vibration sensing module and a microcontroller. The vibration sensing module is configured to detect vibration information generated by feedback from the shock-absorbing module. The microcontroller transmits the vibration information to a cloud server for processing.

In one or more embodiments of the present disclosure, the transport rack further includes a plurality of positioning members. The positioning members are configured to position the shipping box on the transport rack.

In one or more embodiments of the present disclosure, a bottom of the shipping box has a positioning groove. The positioning members are positioning pins and are configured to be inserted into the positioning groove.

In one or more embodiments of the present disclosure, the shipping vehicle further includes a transport vehicle equipped with the inflatable module. The transport vehicle includes a cavity. The cavity is configured to carry the mobile transport device. The inflatable module is configured to dock with the inflatable receiving device and provide the gas to be transmitted to the shipping box through the gas connection port and the gas valve port.

In one or more embodiments of the present disclosure, the inflatable receiving device includes an internal flow channel. The internal flow channel is communicated with the gas connection port.

In one or more embodiments of the present disclosure, the inflatable module includes a humidity sensing module and a microcontroller. The humidity sensing module is configured to measure humidity information in the shipping box. The microcontroller is coupled to the humidity sensing module. The microcontroller is configured to store the humidity information and transmit the humidity information to a cloud server for processing.

Accordingly, in the shipping vehicle of the present disclosure, the problem that conventional transport devices have no inflation function and affect the cleanliness of the semiconductor containers can be solved. The present disclosure utilizes the shipping vehicle with an inflation function. Whether it is short-distance cross-factory transportation or long-distance cross-region transportation, the inflatable module can be docked through the mobile transport device. The inflatable module can be disposed on the transport rack or the transport vehicle, and transmits the gas to the shipping box or to the inside of the semiconductor container through a gas path, thereby maintaining moisture in the shipping box or/and the semiconductor container and reducing the generation of VOC. The present disclosure has multifunctional applications. For example, the shipping vehicle has a vibration detection function and a humidity detection function, which allows operators to obtain relevant information in real time and implement corresponding processing measures, which can solve the problem of product defective rate caused by transportation distance, temperature changes, and storage methods.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a perspective view of a shipping vehicle before carrying shipping boxes according to the present disclosure;

FIG. 1B is a perspective view of the shipping vehicle after carrying the shipping boxes according to the present disclosure;

FIG. 2 is a partial cross-sectional schematic diagram of the shipping vehicle according to the present disclosure;

FIG. 3 is another partial cross-sectional schematic diagram of the shipping vehicle according to the present disclosure;

FIG. 4 is a perspective view of a partially unfolded structure of the transport rack according to the present disclosure;

FIG. 5A is a partial cross-sectional schematic diagram illustrating positioning between the transport rack and the shipping box according to the present disclosure;

FIG. 5B is another partial cross-sectional schematic diagram illustrating the positioning between the transport rack and the shipping box according to the present disclosure;

FIG. 6 is a functional block diagram illustrating a vibration detection function of the shipping vehicle according to the present disclosure;

FIG. 7 is a functional block diagram illustrating a humidity detection function of the shipping vehicle according to the present disclosure;

FIG. 8 is a side view of a shipping vehicle according to the present disclosure; and

FIG. 9 is a partial perspective view of a mobile transport device in FIG. 8.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

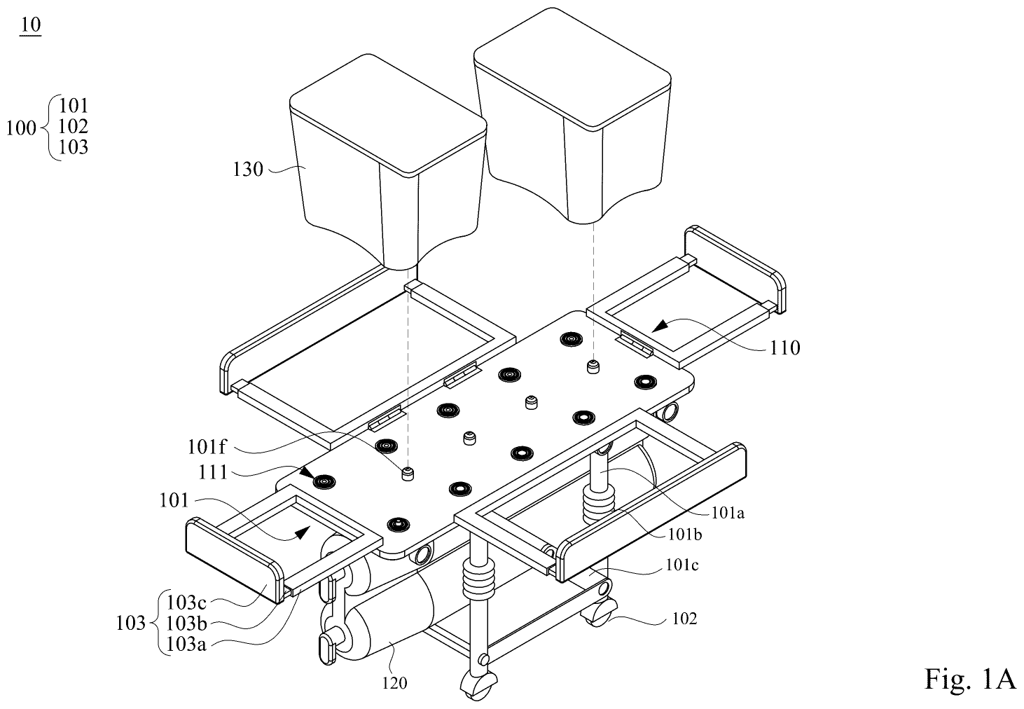

Reference is made to FIG. 1A and FIG. 1B. FIG. 1A is a perspective view of a shipping vehicle 10 before carrying shipping boxes 130 according to the present disclosure. FIG. 1B is a perspective view of the shipping vehicle 10 after carrying the shipping box 130 according to the present disclosure, in which the shipping boxes 130 are carried on a transport rack 101 and are represented by dotted lines. The shipping vehicle 10 includes a mobile transport device 100, an inflatable module 120, and the shipping boxes 130. The mobile transport device 100 includes an inflatable receiving device 110 and a plurality of gas connection ports 111 connected to the inflatable receiving device 110. The mobile transport device 100 may be configured with the shipping boxes 130 at the same time. The gas connection ports 111 include an inflation port, an exhaust port, a combination thereof, or one of them. The gas connection ports 111 match gas valve ports 131 of the shipping boxes 130. The gas valve ports 131 receive gas and transmit the gas to the shipping boxes 130, which will be described in detail later.

The inflatable module 120 is configured on the mobile transport device 100. The inflatable module 120 is configured to dock with the inflatable receiving device 110 and provide the gas to be transmitted to the gas connection ports 111. The shipping boxes 130 are carried on the mobile transport device 100. The mobile transport device 100 further includes a transport rack 101 and a plurality of wheels 102. The inflatable receiving device 110 is configured on the transport rack 101. The transport rack 101 is configured to carry the shipping boxes 130. The wheels 102 are disposed on the transport rack 101 and configured to move the transport rack 101.

In the present embodiment, the inflatable module 120 configured on the transport rack 101 is a gas storage bottle, but the present disclosure is not limited thereto. In some embodiments, the gas storage bottle stores, for example, extreme clean dry air (XCDA).

As shown in FIG. 1B, in the present embodiment, one of the shipping boxes 130 is configured to accommodate a semiconductor container 300a, such as a front opening unified pod (FOUP). Another of the shipping boxes 130 is configured to accommodate a semiconductor container 300b, such as a reticle box or a EUV pod. The shipping boxes 130 are not limited to the type of the semiconductor containers 300a and 300b contained therein.

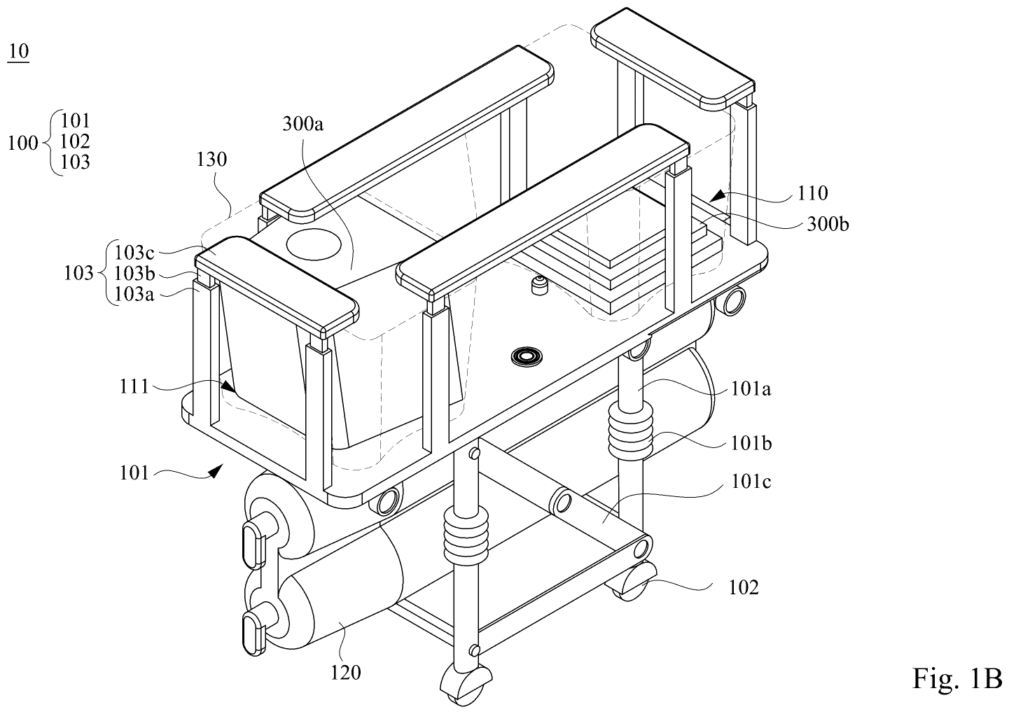

Reference is made to FIG. 2. FIG. 2 is a partial cross-sectional schematic diagram of the shipping vehicle 10 according to the present disclosure. As shown in FIG. 2, the inflatable receiving device 110 includes an internal flow channel 112. The internal flow channel 112 is disposed in the transport rack 101. The internal flow channel 112 is communicated with the gas connection port 111. A position of the gas valve port 131 corresponds to a position of the gas connection port 111. The gas valve port 131 receives the gas from the gas connection port 111 of the inflatable receiving device 110 and transmits the gas to the shipping box 130. By injecting the gas into the shipping boxes 130 and purging the semiconductor containers 300a and 300b contained in the shipping boxes 130, the humidity in the shipping boxes 130 can be maintained below 15%. At the same time, the temperature changes of the semiconductor containers 300a and 300b can also be controlled to effectively suppress the generation of volatile organic compounds (VOC) in the semiconductor containers 300a and 300b.

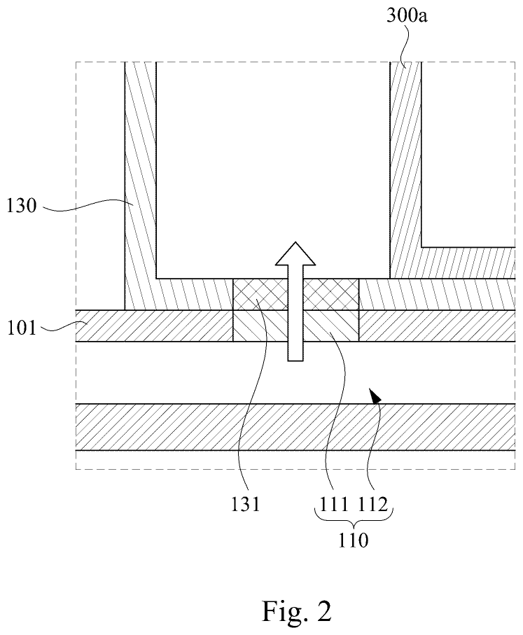

Reference is made to FIG. 3. FIG. 3 is another partial cross-sectional schematic diagram of the shipping vehicle 10 according to the present disclosure. A bottom of the semiconductor container 300a has a gas receiving portion 310 matching the gas connection port 111 and the gas valve port 131, and communicated with each other. The inflatable module 120 is configured to provide the gas. The path that the gas travels includes the internal flow channel 112, the gas connection port 111, the gas valve port 131, and the gas receiving portion 310. The gas receiving portion 310 is configured to receive the gas and transfer the gas to the semiconductor containers 300a and 300b through the gas valve ports 131 of the shipping boxes 130, so as to achieve the purpose of introducing gas into the semiconductor containers 300a and 300b.

As shown in FIG. 1A and FIG. 1B, the mobile transport device 100 further includes a telescopic frame 103. The telescopic frame 103 is disposed on the transport rack 101. The telescopic frame 103 is configured to surround and fix the shipping boxes 130 on the transport rack 101. Specifically, the telescopic frame 103 includes a first rod body 103a, a second rod body 103b, and a pressing plat 103c. The first rod body 103a is connected to the transport rack 101 and configured to abut against side walls of the shipping boxes 130. The second rod body 103b is sleeved with the first rod body 103a and configured to linearly slide relative to the first rod body 103a. The present disclosure does not limit the connection method between the second rod body 103b and the first rod body 103a. As long as the length can be telescopically adjusted, it falls within the claimed scope of the present disclosure. The pressing plate 103c is connected to one end of the second rod body 103b and away from the first rod body 103a. The pressing plate 103c is configured to abut against and fix the shipping boxes 130. In this way, the telescopic frame 103 of the present embodiment can be adjusted according to the size of the shipping boxes 130 to achieve the function of fixing the urgent the shipping boxes 130.

As shown in FIG. 1A and FIG. 1B, the structural design of the mobile transport device 100 is further described in detail. The mobile transport device 100 is an adjustable transport rack and further includes a first leg portion 101a, a shock-absorbing module 101b, and a second leg portion 101c. The first leg portion 101a is connected between the transport rack 101 and the wheels 102, and the inflatable receiving device 110 is provided below the transport rack 101. The shock-absorbing module 101b is disposed between the first leg portion 101a and the wheels 102. The second leg portion 101c is connected between the first leg portion 101a and the transport rack 101. The second leg portion 101c is configured to fold the first leg portion 101a parallel to the bottom of the transport rack 101, or to unfold the first leg portion 101a to stand vertically below the transport rack 101. When the mobile transport device 100 moves on an uneven road surface via the wheels 102, the shock-absorbing module 101b connected between the first leg portion 101a and the transport rack 101 can absorb the vibration feedback from the road surface to the wheels 102.

In some embodiments, the shock-absorbing module 101b can use a pneumatic shock absorber, a hydraulic shock absorber, or an elastic member (such as a soft rubber or a spring), but the disclosure is not limited thereto.

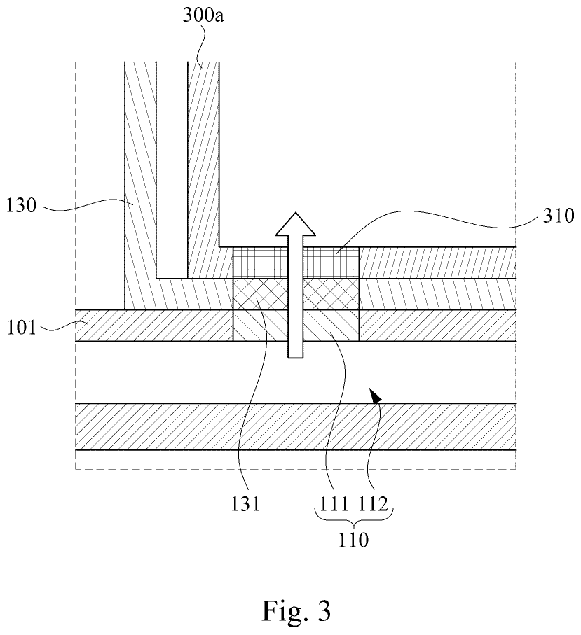

Reference is made to FIG. 1A and FIG. 4. FIG. 4 is a perspective view of a partially unfolded structure of the transport rack 101 according to the present disclosure. The telescopic frame 103 further includes a rotating shaft member 101g. The rotating shaft member 101g is disposed between the first rod body 103a and the transport rack 101. The first rod body 103a is rotated outwardly relative to the transport rack 101 by the rotating shaft member 101g to expand parallelly or rotate vertically to stand on the transport rack 101. In this way, the operators can first rotate and unfold the telescopic frame 103 toward the outside of the transport rack 101, then load the shipping boxes 130 on the transport rack 101, and then rotate the telescopic frame 103 to stand vertically on the transport rack 101, so that the shipping boxes 130 can be conveniently fastened to the transport rack 101.

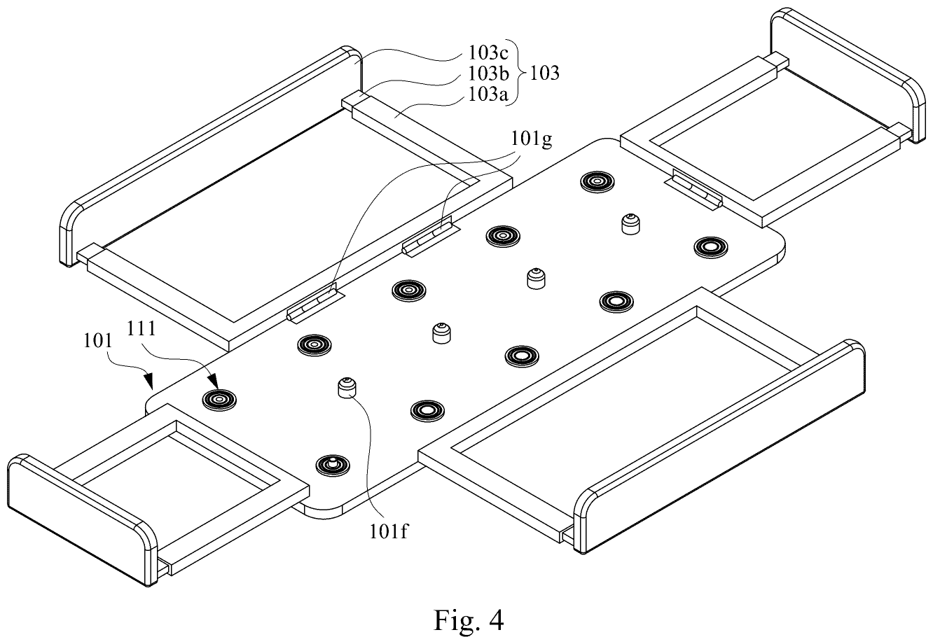

Reference is made to FIG. 5A and FIG. 5B. FIG. 5A is a partial cross-sectional schematic diagram illustrating positioning between the transport rack 101 and the shipping box 130 according to the present disclosure. FIG. 5B is another partial cross-sectional schematic diagram illustrating the positioning between the transport rack 101 and the shipping box 130 according to the present disclosure. As shown in FIG. 1A, FIG. 5A, and FIG. 5B, the transport rack 101 further includes a plurality of positioning members 101f. On the other hand, a bottom of the shipping box 130 has a positioning groove 132. The positioning members 101f are positioning pins and are configured to be inserted into the positioning groove 132. Through the cooperation of the positioning members 101f and the positioning groove 132, the purpose of positioning the shipping box 130 on the transport rack 101 can be achieved.

In the present embodiment shown in FIG. 5A, the positioning groove 132 of the shipping box 130 has a triangular cross-sectional shape. In the present embodiment shown in FIG. 5B, the positioning groove 132 of the shipping box 130 has a rectangular cross-sectional shape. However, the cross-sectional shape of the positioning groove 132 is not limited thereto. In practical applications, as long as the purpose of mutual positioning with the positioning members 101f can be achieved, the positioning groove 132 of the shipping box 130 can be flexibly modified into other specific shapes.

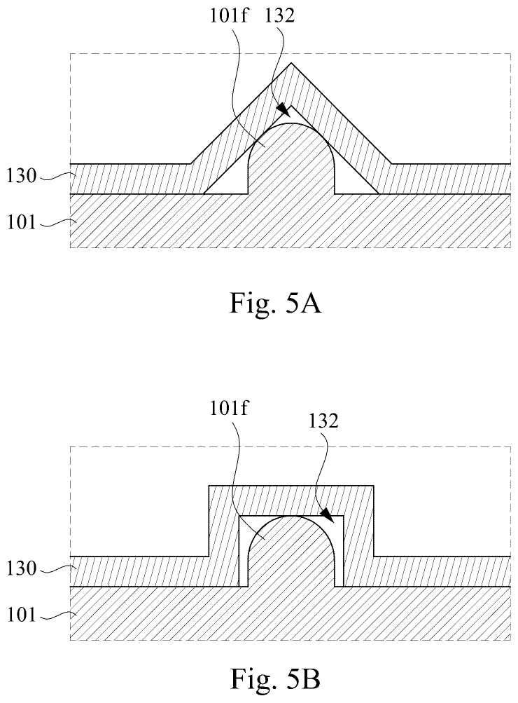

Reference is made to FIG. 6. FIG. 6 is a functional block diagram illustrating a vibration detection function of the shipping vehicle 10 according to the present disclosure. As shown in FIG. 6, the transport rack 101 further includes a vibration sensing module 101d and a microcontroller 101e. The microcontroller 101e is, for example, a programmable logic controller (PLC), but the disclosure is not limited thereto. The vibration sensing module 101d is configured to detect vibration information generated by feedback from the shock-absorbing module 101b. The microcontroller 101e transmits the vibration information to a cloud server 400 for processing, for example, through wireless means. In this way, the operators can handle the abnormal status in real time through the recorded content of the vibration information of the cloud server 400.

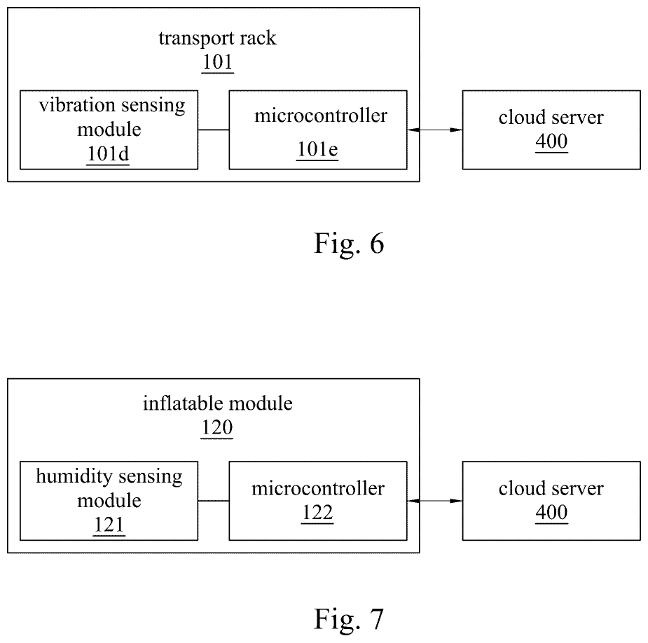

Reference is made to FIG. 7. FIG. 7 is a functional block diagram illustrating a humidity detection function of the shipping vehicle 10 according to the present disclosure. As shown in FIG. 7, the inflatable module 120 includes a humidity sensing module 121 and a microcontroller 122. The microcontroller 122 is, for example, a PLC, but the disclosure is not limited thereto. The humidity sensing module 121 is configured to measure humidity information in the shipping boxes 130. The microcontroller 122 is coupled to the humidity sensing module 121. The microcontroller 122 is configured to store the humidity information and transmit the humidity information to the cloud server 400 for processing, for example, through wireless means. In this way, the operators can adjust the inflation mode in real time to control the internal humidity maintenance level through the recorded content of the humidity information of the cloud server 400, such as the internal humidity information of the shipping boxes 130 from the origin to the destination.

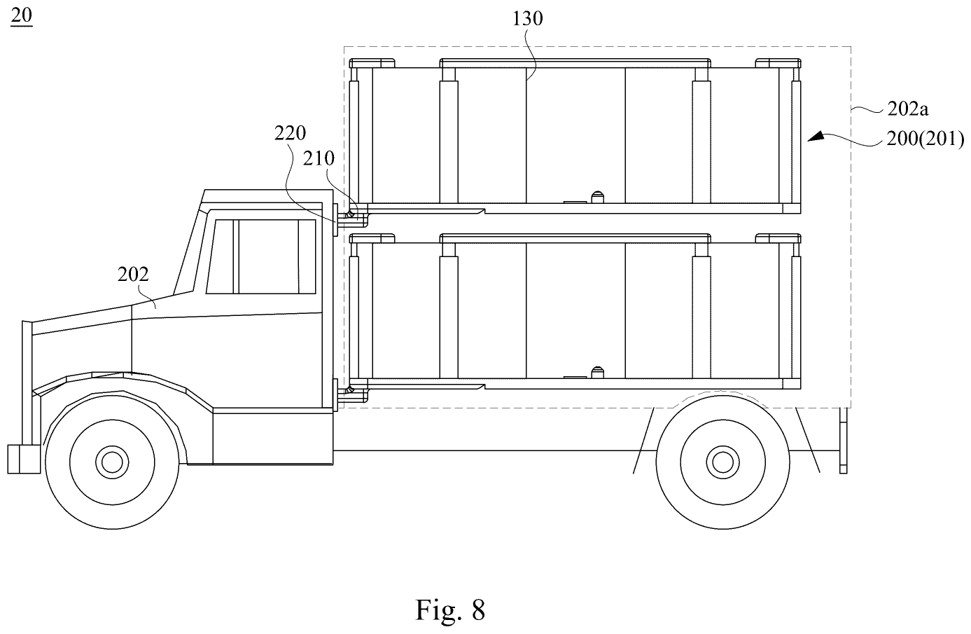

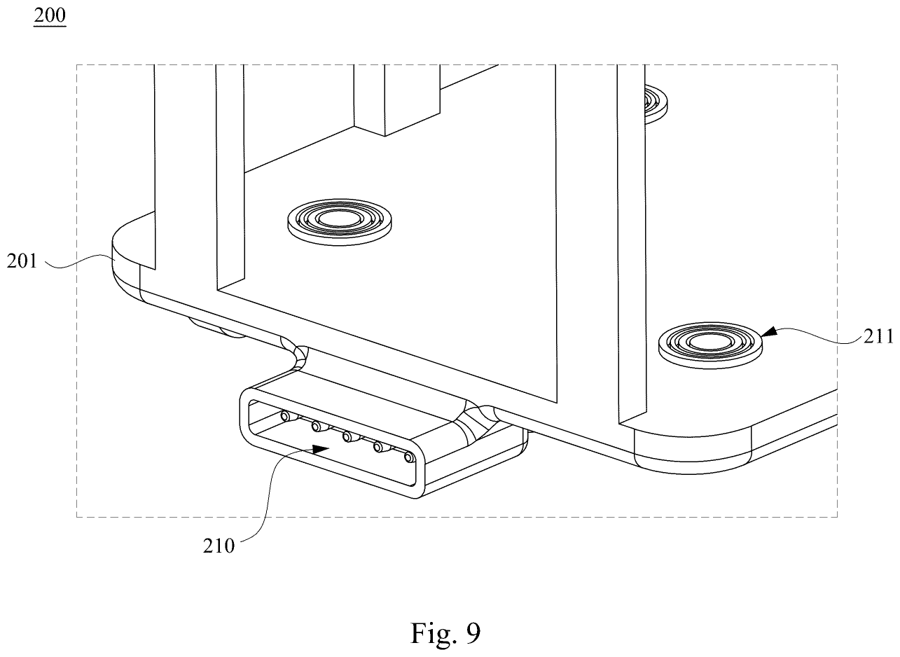

In addition to the semiconductor containers 300a and 300b that can be transported across factory areas (short distance), the present disclosure proposes another embodiment that can be transported across long distances and across regions. Reference is made to FIG. 8 and FIG. 9. FIG. 8 is a side view of a shipping vehicle 20 according to the present disclosure. FIG. 9 is a partial perspective view of a mobile transport device 200 in FIG. 8. As shown in FIG. 8 and FIG. 9, the shipping vehicle 20 further includes a transport vehicle 202. The transport vehicle 202 is equipped with an inflatable module 220. The transport vehicle 202 includes a cavity 202a (Indicated by a dotted line in FIG. 8). The cavity 202a is configured to carry the mobile transport device 200. The inflatable module 220 can be located in the cavity 202a or installed outside the cavity 202a, but the inflatable module 220 must be communicated with the cavity 202a. Since the cavity 202a is a large space and can accommodate multiple mobile transport devices 200, to facilitate transport, the first leg portion 101a can be folded parallel to the bottom of the transport rack 201. The gas transmission path provided by the inflatable module 220 is from the inflatable receiving device 210, the gas connection ports 211, and the gas valve ports 131 (refer to FIG. 2 or FIG. 3) to the shipping boxes 130.

Specifically, the transport vehicle 202 may be equipped with multiple sets of inflatable modules 220. The transport racks 201 are arranged in two layers in a stacked manner in the cavity 202a. The pressing plate 103c (see FIG. 1A for details) can not only be used to abut and fix the shipping boxes 130, but also can be used as a platform for stacking the transport racks 201. The inflatable module 220 can dock with the inflatable receiving device 210, and transmit the gas to the shipping boxes 130 along the gas path, or to the shipping boxes 130 and the semiconductor container 300a/semiconductor container 300b at the same time, so as to maintain a certain humidity inside until reaching the destination. Through this design, a steady stream of gas overflows from the inside of the shipping boxes 130 to the outside, thereby achieving gas circulation in the shipping boxes 130 and achieving predetermined cleanliness and humidity control. Alternatively, a continuous stream of gas is directly filled into the semiconductor containers 300a and 300b, and overflows from the inside to the outside until the shipping box 130 and the semiconductor containers 300a and 300b are all in a positive pressure state, which can prevent particles from entering the semiconductor containers 300a and 300b, while maintaining the same internal temperature of the upper and lower semiconductor containers 300a and 300b, and reducing the generation of VOC.

According to the foregoing recitations of the embodiments of the disclosure, it can be seen that in the shipping vehicle of the present disclosure, the problem that conventional transport devices have no inflation function and affect the cleanliness of the semiconductor containers can be solved. The present disclosure utilizes the shipping vehicle with an inflation function. Whether it is short-distance cross-factory transportation or long-distance cross-region transportation, the inflatable module can be docked through the mobile transport device. The inflatable module can be disposed on the transport rack or the transport vehicle, and transmits the gas to the shipping box or to the inside of the semiconductor container through a gas path, thereby maintaining moisture in the shipping box or/and the semiconductor container and reducing the generation of VOC. The present disclosure has multifunctional applications. For example, the shipping vehicle has a vibration detection function and a humidity detection function, which allows the operators to obtain relevant information in real time and implement corresponding processing measures, which can solve the problem of product defective rate caused by transportation distance, temperature changes, and storage methods.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A shipping vehicle suitable for shipping a semiconductor container, the shipping vehicle comprising:
a mobile transport device comprising an inflatable receiving device and a gas connection port connected to the inflatable receiving device;
an inflatable module configured on the mobile transport device, the inflatable module being configured to dock with the inflatable receiving device and provide a gas to be transmitted to the gas connection port; and
a shipping box carried on the mobile transport device, the shipping box having a gas valve port, a position of the gas valve port corresponding to a position of the gas connection port, the gas valve port receiving the gas and transmitting the gas to the shipping box.

2. The shipping vehicle of claim 1, wherein the inflatable module is a gas storage bottle.

3. The shipping vehicle of claim 1, wherein the shipping box is configured to accommodate the semiconductor container, the semiconductor container has a gas receiving portion matching the gas connection port and the gas valve port, and the gas receiving portion is configured to receive the gas and transfer the gas to the semiconductor container through the shipping box.

4. The shipping vehicle of claim 1, wherein the mobile transport device further comprises a transport rack and a plurality of wheels, the inflatable receiving device is configured on the transport rack, the transport rack is configured to carry the shipping box, and the wheels are disposed on the transport rack and configured to move the transport rack.

5. The shipping vehicle of claim 4, wherein the mobile transport device further comprises a telescopic frame, the telescopic frame is disposed on the transport rack, and the telescopic frame is configured to surround and fix the shipping box on the transport rack.

6. The shipping vehicle of claim 5, wherein the telescopic frame comprises:
a first rod body connected to the transport rack and configured to abut against a side wall of the shipping box;
a second rod body sleeved with the first rod body and configured to linearly slide relative to the first rod body; and
a pressing plate connected to one end of the second rod body and away from the first rod body, the pressing plate being configured to abut against and fix the shipping box.

7. The shipping vehicle of claim 6, further comprising a rotating shaft member disposed between the first rod body and the transport rack, wherein the first rod body is configured to rotate outwardly relative to the transport rack by the rotating shaft member to expand parallelly or rotate vertically to stand on the transport rack.

8. The shipping vehicle of claim 4, further comprising a shock-absorbing module disposed between the transport rack and the wheels, the transport rack comprising a vibration sensing module and a microcontroller, wherein the vibration sensing module is configured to detect vibration information generated by feedback from the shock-absorbing module, and the microcontroller transmits the vibration information to a cloud server for processing.

9. The shipping vehicle of claim 4, wherein the transport rack further comprises a plurality of positioning members, and the positioning members are configured to position the shipping box on the transport rack.

10. The shipping vehicle of claim 9, wherein a bottom of the shipping box has a positioning groove, and the positioning members are positioning pins and are configured to be inserted into the positioning groove.

11. The shipping vehicle of claim 1, further comprising:
a transport vehicle equipped with the inflatable module, the transport vehicle comprising a cavity, the cavity being configured to carry the mobile transport device, the inflatable module being configured to dock with the inflatable receiving device and provide the gas to be transmitted to the shipping box through the gas connection port and the gas valve port.

12. The shipping vehicle of claim 1, wherein the inflatable receiving device comprises an internal flow channel, and the internal flow channel is communicated with the gas connection port.

13. The shipping vehicle of claim 1, wherein the inflatable module comprises:
a humidity sensing module configured to measure humidity information in the shipping box; and
a microcontroller coupled to the humidity sensing module, the microcontroller being configured to store the humidity information and transmit the humidity information to a cloud server for processing.

14. A shipping vehicle suitable for shipping a semiconductor container, the shipping vehicle comprising:
a mobile transport device comprising an inflatable receiving device and a gas connection port connected to the inflatable receiving device;
a transport vehicle equipped with an inflatable module and comprising a cavity configured to accommodate the mobile transport device, wherein the inflatable module is configured to dock with the inflatable receiving device and provide a gas to be transmitted to the gas connection port; and
a shipping box carried on the mobile transport device and having a gas valve port communicated with the gas connection port.

15. The shipping vehicle of claim 14, wherein the shipping box is configured to accommodate the semiconductor container, and the semiconductor container has a gas receiving portion communicated with the gas valve port.
